(19) United States
(12) Patent Application Publication
(10) Pub. No.: US 2004/0226735 A1
(43) Pub. Date: Nov. 18, 2004

(54) Method and apparatus for integrated noise decoupling

(76) Inventors: Ping Wu, Cupertino, CA (US); Datong Chen, Fremont, CA (US); Renyong Fan, Cupertino, CA (US); Jin Ji, Sunnyvale, CA (US)

Correspondence Address: PERKINS COIE LLP, PATENT-SEA, P.O. BOX 1247, SEATTLE, WA, 98111-1247, US

(21) Appl. No.: 10/438,292

(22) Filed: May 12, 2003

(51) Int. Cl. H02G 3/08

(52) U.S. Cl. 174/52.1

(57) ABSTRACT

A method and apparatus for large scale noise decoupling in an integrated circuit is disclosed herein. A power decoupling mesh and a power distribution structure are included in the integrated circuit. The power decoupling mesh is configured in accordance with the power distribution structure. The power decoupling mesh comprises a plurality of decoupling capacitors, such as trench capacitors or MOSFETs.

### BACKGROUND

The present invention relates generally to integrated circuits. More particularly, the present invention relates to noise decoupling of integrated circuits.

Power distribution, high-speed operation, and/or lower power consumption features are common in integrated circuit (IC) chips. Such features, however, increase the parasitic effects of resistances and inductances within the chip so that power distribution-related noise occurs.

Decoupling capacitor(s) located at areas of the chip where the noise signals are most prominent or undesirable provides isolation or reduction of such noise. Decoupling capacitors, also referred to as power decouplers or bypass capacitors, effect power decoupling of noise signals during turn-on of power as well as when the circuitry is in an operational mode. Decoupling capacitors are configured to maintain the voltage level in a given local area of the chip in the presence of current transients.

For multi-powered integrated circuits (ICs) and devices, i.e., ICs and devices included in a semiconductor chip having two or more different operating power requirements, or for chips having extensive power distribution systems, localized power decoupling is insufficient in isolating or reducing the noise. Since providing power to the chip itself can introduce noise, increasing the number of power supplies increases the noise problem. Higher capability chips are also prone to noise problems, because, for example, the noise margin is smaller for higher capability chips. Higher density chips are also prone to noise problems.

Hence, there is a need for effective power decoupling throughout the chip. There is a further need for large scale power decoupling without undue performance, cost, design, or space considerations. There is still a further need for large scale power decoupling at the chip, die, package and/or board level.

### SUMMARY

One embodiment of the invention relates to a method for reducing power distribution related noise in an integrated circuit. The method includes distributing power throughout the integrated circuit using a power distribution structure. The method further includes forming a decoupling mesh in the integrated circuit in accordance with the power distribution structure to reduce the noise throughout the integrated circuit, and connecting the power distribution structure to the decoupling mesh.

Another embodiment of the invention relates to a decoupling mesh. The mesh includes a first decoupling capacitor coupled to a power plane and a ground plane of a power distribution structure. The mesh further includes a second decoupling capacitor displaced from the first decoupling capacitor and coupled to the power plane and the ground plane. The layout of the first and second decoupling capacitors and the power distribution structure are integrated with each other.

Still another embodiment of the invention relates to a system for large scale noise reduction in an integrated circuit. The system includes a power ring around the periphery of the integrated circuit, a first power linear layer traversing the integrated circuit, and a second power linear layer traversing the integrated circuit. The system further includes a first set of decoupling capacitors overlaid to the position of the first power linear layer, and a second set of decoupling capacitors overlaid to the position of the second power linear layer. The second power linear layer is spaced apart from and parallel with the first power linear layer. The first and second sets of decoupling capacitors are configured to maintain a voltage level in the areas of the integrated circuit proximate to the corresponding first and second power linear layers in the presence of a current transient. The power ring, the first power linear layer, and the second power linear layer comprise a power distribution system for the integrated circuit.

### BRIEF DESCRIPTION OF THE DRAWINGS

FIG. 1 is a top view of a semiconductor chip or common substrate including a power distribution structure and a power decoupling mesh.

FIG. 2 is a top view of another semiconductor chip or common substrate including a power distribution structure and a power decoupling mesh.

FIG. 3 is a top view of still another semiconductor chip or common substrate including a power distribution structure and a power decoupling mesh.

FIG. 4 is a cross-sectional side view of the chip illustrated in FIGS. 1 and 3.

FIG. 5 is a detailed top view of a portion of the chip illustrated in FIG. 2.

In the drawings, identical reference numbers identify identical or substantially similar elements or acts. To easily identify the discussion of any particular element or act, the most significant digit or digits in a reference number refer to the Figure number in which that element is first introduced (e.g., element 1104 is first introduced and discussed with respect to FIG. 11).

### DETAILED DESCRIPTION

Described in detail below is a method and apparatus for a power decoupling mesh for a semiconductor chip, die, or package. The power decoupling mesh is configured to reduce power distribution-related noise among different areas of a circuit, reduce noise within a local area of the circuit, and/or reduce the power bounce due to a logic circuit swing. The power decoupling mesh is configured to provide power decoupling of noise associated with the power sources as well as to improve noise immunity.

The following description provides specific details for a thorough understanding of, and enabling description for, embodiments of the invention. However, one skilled in the art will understand that the invention may be practiced without these details. In other instances, well-known structures and functions have not been shown or described in detail to avoid unnecessarily obscuring the description of embodiments of the invention.

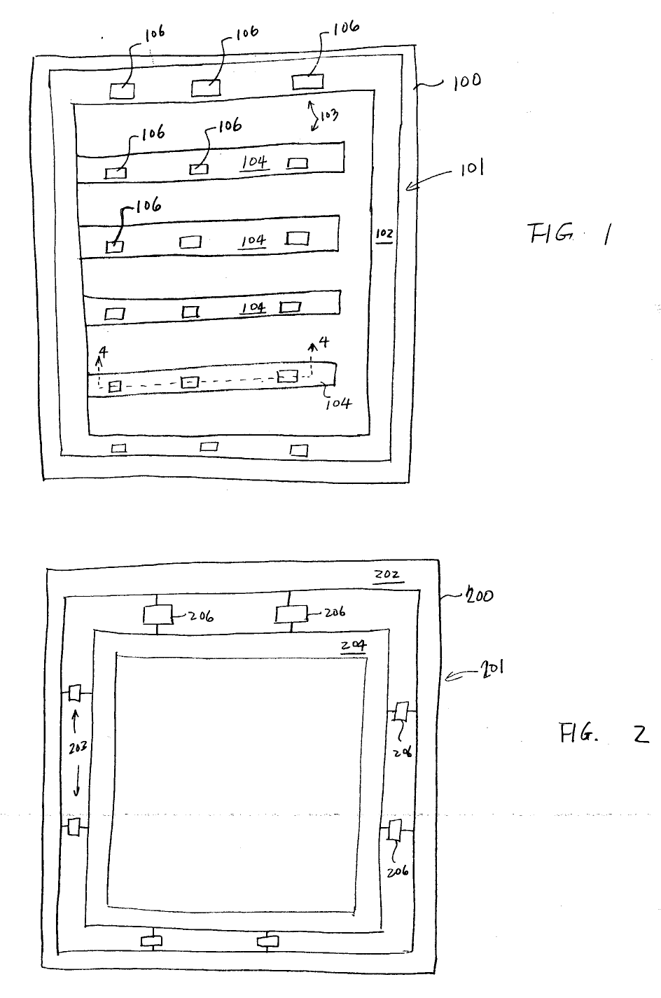

Referring to FIG. 1, a top view of a substrate or chip 100 is shown. The chip 100 includes a power distribution structure 101 and a power decoupling mesh 103. The power distribution structure 101 comprises a power ring 102, formed around the periphery of the chip 100, and a series of spaced apart parallel metallization layers or wires 104 which traverse the chip 100 within the inside of the power ring 102. The power distribution structure 101, also referred to as a power mesh or a power ring structure, is configured to distribute power to the various circuits (not shown) formed on the chip 100.

The power decoupling mesh 103 comprises a set of decoupling capacitors 106 in accordance with the power distribution structure 101. The decoupling capacitors 106 are provided perpendicular to the plane of the power distribution structure 101. Although three decoupling capacitors per row are shown in FIG. 1, more or less numbers of decoupling capacitors may be provided, depending on noise reduction or immunity considerations.

Referring to FIG. 2, a top view of a substrate or chip 200 is shown. The chip 200 includes a power distribution structure 201 and a power decoupling mesh 203. The power distribution structure 201 comprises an outer power ring 202 and an inner power ring 204. The outer power ring 202 is formed around the periphery of the chip 200. The inner power ring 204 is formed inside and concentric with the outer power ring 202. The power decoupling mesh 203 comprises a series of decoupling capacitors 206 provided between the outer and inner power rings 202 and 204.

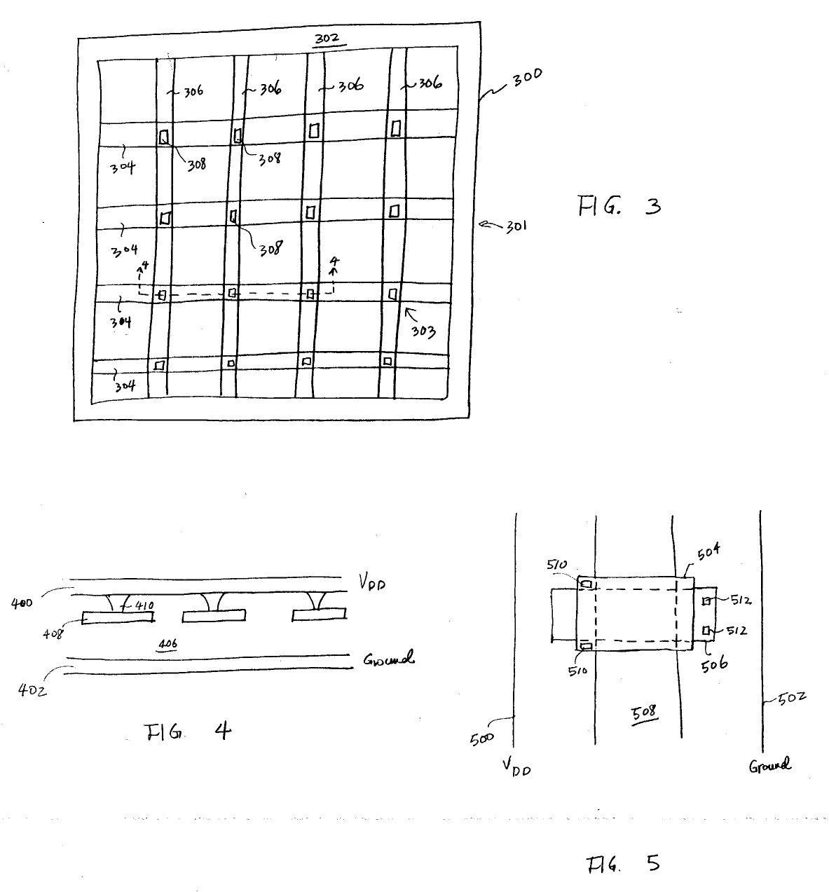

Referring to FIG. 3, a top view of a substrate or chip 300 is shown. The chip 300 includes a power distribution structure 301 and a power decoupling mesh 303. The power distribution structure 301 comprises a power ring 302, a first series of parallel metallization layers or wires 304, and a second series of parallel metallization layers or wires 306. The power ring 302 is formed around the periphery of the chip 300. The first series of layers 304 are spaced apart from each other and traverse the chip 300 in a first direction inside the power ring 302. The second series of layers 306 are spaced apart from each other and traverse the chip 300 in a second direction (the second direction substantially perpendicular to the first direction) inside of the power ring 302. The power decoupling mesh 303 comprises decoupling capacitors 308 located at each intersection of the first and second series of layers 304, 306. Hence, the decoupling capacitors 308 form a matrix in the chip 300.

The power distribution structures 101, 201, and 301 (power distribution structures also referred to as power supply buses) are formed of a conductive material, such as a metal or polysilicon. Although the power distribution structures and power decoupling meshes are shown visible in the top views of the chips 100, 200, 300, all or portions of the power distribution structures and/or the power decoupling meshes may alternatively be hidden by circuits and other structures included in the chips. For example, in FIG. 3, the second series of layers 306 may be formed below the first series of layers 304 and thus be hidden from view. The decoupling capacitors 106, 206, and 308 may also be formed below the top layer or structures of the chips 100, 200, 300, respectively, and thus not be visible from the top. Providing the power distribution structures and the power decoupling meshes, or portions thereof, at two or more levels or depth within the chips promotes efficient use of space, device isolation, and/or fabrication processes.

The decoupling capacitors are distributed in conjunction with the power distribution structure. The power decoupling mesh is configured for large scale and integrated noise decoupling and isolation in all areas of the chip where noise is likely to occur. The power decoupling mesh is adjacent, overlaid, and/or integrated with the power distribution structure. The power decoupling mesh is designed to complement the power distribution structure, and as such, the power distribution structures and power decoupling meshes are not limited to those shown in FIGS. 1-3. Instead, a variety of power distribution structures traversing all or a portion of the chip may be implemented, in accordance with the power requirements of circuits and devices on the chip, and the exact location of the decoupling capacitors are complementarily determined.

The decoupling capacitors can be located under the power distribution structure. In FIGS. 1 and 3, the decoupling capacitors 106 and 308 are formed under the power distribution structures 101 and 301, respectively. In FIG. 4, a cross-sectional side view of the chip 100 is shown. A power plane 400, comprising the power distribution structure 101, is provided above a ground plane 402. The ground plane 402 may be a semiconductor substrate or a metallization layer.

Between the power plane 400 (also referred to as a power bus or power supply bus) and the ground plane 402 are the decoupling capacitors 106. For each of the decoupling capacitors 106, a via 410 couples the power plane 400 to an electrode 408, and the electrode 408 and the ground plane 402 sandwich a dielectric material 406. The decoupling capacitors 106 and their connection to the power and ground planes 400, 402 are formed using semiconductor fabrication processes well-known in the art.

The cross-sectional view shown in FIG. 4 can also be of the chip 300. Similar to the discussion above, the power plane 400 comprises the first series of layers 304, the ground plane 402 comprises the second series of layers 306, and the decoupling capacitors 308 formed therebetween. Alternatively, the power plane 400 may comprise the first series of layers 304, the electrode 408 may comprise the second series of layers 306, and the ground plane 402 may be a separate substrate or metallization layer. In chips 100 and 300, vias or other interconnect structures would be provided between the power and ground planes in the absence of the decoupling capacitors. Thus, the power decoupling mesh does not require additional space or displacement of otherwise existing structures.

When the power and ground planes are in the same plane, the decoupling capacitors can be configured as shown in FIGS. 2 and 5. In FIG. 5, a top view of one of the decoupling capacitors 206 positioned between a power plane 500 and a ground plane 502 is shown. A dielectric material 508 is sandwiched between a first electrode 504 and a second electrode 506. The dielectric material 508 is provided below the first electrode 504. The second electrode 506 is provided below the dielectric material 508. Vias 510 provide electrical contact between the electrodes 504 and the power plane 500. Vias 512 provide electrical contact between the electrode 506 and the ground plane 502.

Although capacitors are discussed herein with respect to the power decoupling mesh, other devices or structures may be implemented to provide the noise immunity and/or reduction. For example, metal oxide semiconductor field-effect transistors (MOSFETs) may be used as decoupling capacitors. The capacitors may also be trench capacitors, stack capacitors, metal-insulator-metal, or other types of capacitors.

The power decoupling mesh may be implemented with a variety of other power distribution structures. Power distribution structures may be of various complexity, density, one or more power supplies (e.g., one or more different power planes), and/or configurations. The power decoupling mesh may also be extended beyond the chip to the die or package area.

Accordingly, a method and system for a large scale power decoupling mesh is disclosed herein. The power decoupling mesh is configured to integrate with and/or complement a power distribution structure provided in the chip, die, and/or package. The power decoupling mesh provides immunity and/or reduction of power distribution-related noise at a circuit, among sections of a circuit, and along points where voltage drop occurs. In this manner, noise protection is provided throughout the circuitry.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular words, respectively. Additionally, the words “herein,” “above,” “below,” and words of similar import, when used in this application, shall refer to this application as a whole and not to any particular portion of this application.

The above description of illustrated embodiments of the invention is not intended to be exhaustive or to limit the invention to the precise form enclosed. While specific embodiments of, and examples for, the invention are described herein for illustrative purposes, various equivalent modifications are possible within the scope of the invention, as those skilled in the relevant art will recognize.

I/We claim:

1. A method for reducing power distribution related noise in an integrated circuit, the method comprising:
distributing power throughout the integrated circuit using a power distribution structure;
forming a decoupling mesh in the integrated circuit in accordance with the power distribution structure to reduce the noise throughout the integrated circuit; and
connecting the power distribution structure to the decoupling mesh.

2. The method of claim 1, wherein the decoupling mesh comprises a plurality of capacitors.

3. The method of claim 1, wherein the decoupling mesh comprises a plurality of transistors.

4. The method of claim 1, wherein forming a decoupling mesh includes forming the decoupling mesh under the power distribution structure.

5. The method of claim 1, wherein forming a decoupling mesh includes forming the decoupling mesh in the same location or adjacent to the power distribution structure.

6. A decoupling mesh, comprising:
a first decoupling capacitor coupled to a power plane and a ground plane of a power distribution structure; and
a second decoupling capacitor displaced from the first decoupling capacitor and coupled to the power plane and the ground plane,
wherein the layout of the first and second decoupling capacitors and the power distribution structure are integrated with each other.

7. The decoupling mesh of claim 6, wherein the power plane is above the ground plane and the first and second decoupling capacitors are provided between the power and ground planes.

8. The decoupling mesh of claim 7, wherein the first decoupling capacitor comprises a via coupled to the power plane, an electrode coupled to the via, and a dielectric material coupled to the electrode and the ground plane.

9. The decoupling mesh of claim 6, wherein the power and ground planes are in-plane relative to each other.

10. The decoupling mesh of claim 9, wherein the first decoupling capacitor comprises:
a first via coupled to the power plane;
a first electrode coupled to the first via;
a second via coupled to the ground plane;
a second electrode coupled to the second via; and
a dielectric material coupled between the first and second electrodes.

11. The decoupling mesh of claim 6, wherein the first decoupling capacitor is at least one of a trench capacitor, a stack capacitor, a metal-insulator-metal capacitor, and a MOSFET.

12. The decoupling mesh of claim 6, wherein the power plane includes a power ring.

13. The decoupling mesh of claim 6, wherein the power distribution structure and the first decoupling capacitor are provided in a chip.

14. The decoupling mesh of claim 6, wherein the power distribution structure and the first decoupling capacitor are provided in a die.

15. The decoupling mesh of claim 6, wherein the power distribution structure and the first decoupling capacitor are provided in a chip package.

16. A system for large scale noise reduction in an integrated circuit, comprising:
a power ring around the periphery of the integrated circuit;
a first power linear layer traversing the integrated circuit;
a second power linear layer traversing the integrated circuit, spaced apart from and parallel with the first power linear layer;
a first set of decoupling capacitors overlaid to the position of the first power linear layer; and
a second set of decoupling capacitors overlaid to the position of the second power linear layer, wherein the first and second sets of decoupling capacitors are configured to maintain a voltage level in the areas of the integrated circuit proximate to the corresponding first and second power linear layers in the presence of a current transient, and the power ring, the first power linear layer, and the second power linear layer comprise a power distribution system for the integrated circuit.

17. The system of claim 16, wherein the power ring, the first power linear layer, and the second power linear layer are electrically coupled to each other.

18. The system of claim 16, further comprising:
a third power linear layer traversing the integrated circuit in a direction substantially normal to the first power linear layer; and
a fourth power linear layer traversing the integrated circuit in the direction substantially normal to the first power linear layer, spaced apart from and parallel with the third power linear layer,
wherein the first and second sets of decoupling capacitors are positioned at the intersections of the first, second, third, and fourth power linear layers with each other.

19. The system of claim 16, wherein each of the first and second sets of decoupling capacitors is a trench capacitor, a stack capacitor, or a metal-insulator-metal capacitor.

20. The system of claim 16, wherein each of the first and second sets of decoupling capacitors is a MOSFET.
